(19) United States
(12) Patent Application Publication
(10) Pub. No.: US 2011/0138255 A1
(43) Pub. Date: Jun. 9, 2011

(54) Probabilistic Learning-Based Decoding of Communication Signals

(76) Inventor: Daniel Chonghwan Lee, Burnaby (CA)

(21) Appl. No.: 12/634,686

(22) Filed: Dec. 9, 2009

(51) Int. Cl. H03M 13/13; G06F 11/10

(52) U.S. Cl. 714/777; 714/752; 714/E11.032

(57) ABSTRACT

Methods and apparatus for recovering source data from noisy encoded signals apply population-based probabilistic learning algorithms. Non-converging data elements may be resolved by selective local searches. Initial populations are constructed from the data contents of the message bit positions of the received sequence, which resulted from encoding by a systematic code and channel distortion and noise.

### CROSS-REFERENCE TO RELATED APPLICATIONS

This application claims the benefit of U.S. provisional patent application No. 61/193,567 filed 8 Dec. 2008.

### TECHNICAL FIELD

The application relates to data communication, signal processing, computer, and optimization.

### BACKGROUND

Modern advance in computing technology enables complex decoding processes to be implemented in practical engineering systems. This allows a broader class of error control codes (e.g., block code with a large block size such as low density parity check codes, turbo codes, etc.) to be candidates for practical systems. Indeed some of these codes achieve performance very close to the fundamental limit [1]. Typically, the longer the unit length is, the better is the performance (data throughput under a fixed requirement of fidelity criterion such as the bit error probability). For example, the performance of low density parity check code becomes very close to the fundamental limit as the length of the block increases. The longer block length is especially important for improving performance in some wireless communication systems in which the channel condition changes with time and the transmitter does not have the information of the current channel condition. However, longer data unit increases the computational complexity of the codes. For example, computational complexity of decoding algorithms will increase with the increase of block length in a block code. As an important illustration, let us consider a binary block code that has block length n and has 2^{k} code words. (Thus, each codeword block of n bits carries k bits of information and we say that the code rate is k/n.) For simple illustration, let us consider that the n bits in a block go through a channel and come out of the channel with some bits changed probabilistically. The decoder's function is to decide which of the 2^{k} code words entered the channel on the basis of the n bits received and possibly containing bit errors. Let us denote by Y (an n-dimensional binary vector) the received bits and let us index code words by iε{1, 2, . . . , 2^{k}}. In most systems optimal performance is achieved by maximum a posteriori probability (MAP) detection—that is, to choose codeword i that maximizes the a posteriori probability P(i|Y)=P(i,Y)/P(Y)=P(i|Y)=P(i,Y)/P(Y) for the particular received signal Y. For this maximization, exhaustive search will have to consider 2^{k} code words. Therefore, if we fix code rate (r=k/n=0.5, for example) and increase the block length n, then the computational complexity of the exhaustive search will increases exponentially; i.e., O(2^{k})=O(2^{nr}). Even modern computation technology run into a problem if the block size is large.

Decoding algorithms typically take advantage of algebraic structure of the particular code being used in order to reduce computational complexity. Another approach would be to design a computationally efficient algorithm that does not guarantee choosing a codeword attaining the exact MAP but rather tends to choose a codeword with a posteriori probability close the MAP. For example, genetic algorithms have been suggested for decoding linear block codes in
F. A. C. M. Cardoso and D. S. Arantes, “Genetic decoding of linear block codes,” Proceedings of the 1999 Congress on Evolutionary Computation, vol. 3, pp. 2302-2309.
   Also, as a suboptimal detector, a Genetic Algorithm Detector (GAD) based STBC-MIMO detector was proposed in
Y. Du and K. T. Chan, “Improved Multiuser Detector Employing Genetic Algorithm in a Space-Time Block Coded System”, EURASIP J. of Applied Signal Processing, pp. 640-648, 2004
   A drawback of GAD is that it requires several parameter values to be fine-tuned to achieve good results. Also, in GAD it is difficult to predict the evolution of the population, and good blocks or code words can be broken by the effect of crossover operators.

### SUMMARY

This description presents methods and apparatus for using probabilistic learning algorithms such as, inter alia, estimation of distribution algorithm (EDA), cross-entropy optimization, ant colony, etc. to select the code word on the basis of received signals.

The methods and apparatus may be embodied in numerous engineering systems that include communication systems, sensors, storage and/or retrieval devices.

Embodiments of our method use and configure population-based evolutionary algorithms, and an aspect of the invention provides methods of generating initial populations for these algorithms. Such methods include representing a possible solution by constructing an initial feed vector constituted by the contents of message bit positions in the received signal of a systematic code and generating multiple vectors by choosing the set of vectors close to the initial feed vector in a distance metric in the vector space. Another aspect of the invention allows the methods to configure the population-based algorithm in order to prevent premature convergence to a local optimum.

Further aspects of the invention and features of specific embodiments of the invention are described below.

### BRIEF DESCRIPTION OF THE DRAWINGS

FIG. 1 is a general block diagram of communication systems, which shows where an embodiment of a decoding method fits in.

FIG. 2 is a detailed block diagram of storage systems, which shows where an embodiment of the present s fits in.

FIG. 3 is a flow chart of conventional Estimation of Distribution Algorithms

FIG. 4 is a flow chart of the improved method of applying an EDA by adding a threshold on estimated distributions.

FIG. 5A and FIG. 5B present a flow chart of the improved method of applying EDA by using scattered local search (SLS).

FIG. 6 is a graph that analogically depicts the traveling paths of the ants in ant colony optimization.

FIG. 7 is a block diagram of space-time block coding system.

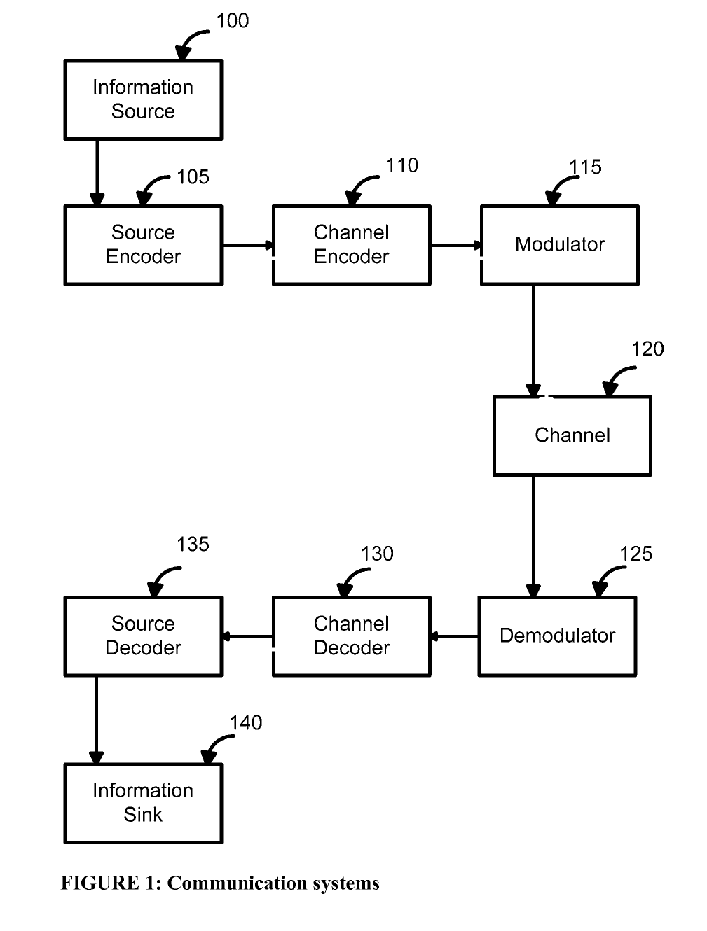

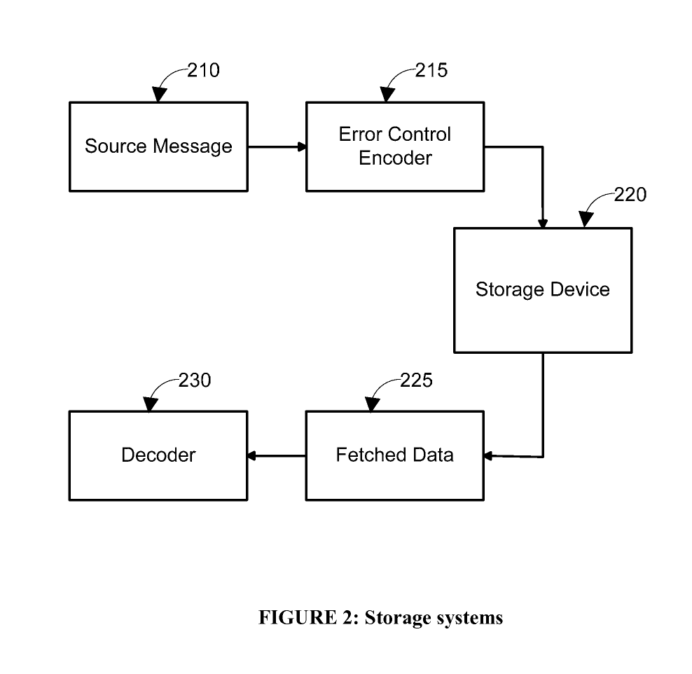

### DETAILED DESCRIPTION

### 1. Modeling for Computationally Efficent Detection Process

Let us denote by [symbol] the set of message symbols. We denote by [symbol] the number of elements in set [symbol] so the size of the symbol alphabet is [symbol] . We denote by [symbol] the l-fold Cartesian product of [symbol] or equivalently the set of all l-dimensional vectors whose components are symbols in [symbol] . For example, in the case of binary symbols, set [symbol] is {0,1} and [symbol] is the set of all 2^{l} binary vectors. We denote a source (user) message by k-dimensional vector mₛ in [symbol] which can carry k user symbols representing information. (We can have up to [symbol] distinct user messages.) We represent a codeword by n-dimensional row vector, c in [symbol] where [symbol] is a set of coded symbols to which each component of c belongs. For each user message m, we can assign a distinct corresponding codeword c as long as the number of possible messages is smaller than the number [symbol] of code words. This deterministic mapping from the set ( [symbol] or a subset of [symbol] ) of messages to Cⁿ defines the coding method. We note that most coding methods in practice use the same set of alphabets for the message symbols and code symbols; i.e., in most coding methods we have [symbol] . Also we note that binary codes use set {0,1} for both [symbol] and [symbol] .

The methods presented in this document are applicable for both the class of systems (for example, communication systems, storage and retrieval systems, etc.) that employ hard decision rule and the class of systems that employ soft decision rule for decoding. For the case of hard decision decoding, we can represent the received signal by an element y in a finite set. The channel can be then modeled by conditional probabilities

Pr(y|mₛ),∀mₛε [symbol] ∀y (1)

This channel characteristics or estimate of this channel statistics is often assumed to be known to the decoder in communication engineering The method described in the present document can be embodied in the decoding processes that find a good (may be suboptimal) solution or solutions within sufficiently short time to the following optimization problem:

$${max}_{{m}_{s} ∈ {ℳ}^{k}} Pr ( {m}_{s} \vert y ) or equivalently {max}_{{m}_{s} ∈ {ℳ}^{k}} Pr ( {m}_{s} ) Pr ( y \vert {m}_{s} ) \qquad ( 2 )$$

on the basis of received signal y. P(mₛ) in expression (2) is the a priori probability that the message is mₛ. A posteriori probability in (2) is

Pr(mₛ|y)=Pr(mₛ,y)/Pr(y)=Pr(mₛ)Pr(y|mₛ)/Pr(y),

so for each particular received signal y we have

$$\begin{matrix}arg {max}_{{m}_{s} ∈ {ℳ}^{k}} Pr ( {m}_{s} \vert y ) = arg {max}_{{m}_{s} ∈ {ℳ}^{k}} Pr ( {m}_{s} , y ) \\ = arg {max}_{{m}_{s} ∈ {ℳ}^{k}} Pr ( {m}_{s} ) Pr ( y \vert {m}_{s} ) .\end{matrix}$$

In many communication systems, the encoder is designed in such a way that Pr(mₛ)=1/ [symbol] ∀mₛε [symbol] (equally likely a priori). In this case the maximization is reduced to maximum likelihood decision:

$${max}_{{m}_{s} ∈ {ℳ}^{k}} Pr ( y \vert {m}_{s} ) \qquad ( 3 )$$

For the case of soft decision decoding, the signal received is represented as a vector of real numbers, yε [symbol] where we denote by l the dimension of the vector. In a special example embodiment of an M-ary IQ (in-phase quadruture-phase) modulation and binary messages and binary code, each binary coded message in [symbol] is mapped to (n/log₂ M)-dimensional vector of complex numbers through coding and modulation, where the real and imaginary parts of each complex number represents the in-phase and quadruture-phase component of each symbol signal. After going through the channel, the received signal will contain some noise and possible channel distortion, and the received signal can be still represented as (n/log₂ M)-dimensional vector of complex numbers. Note that (n/log₂ M)-dimensional vector of complex numbers can be equivalently represented by (2n/log₂ M)-dimensional vector of real numbers. In summary, for the case of soft decision decoding, maximum a posteriori detection of the transmitted/stored message can be performed by the following optimization:

$${max}_{{m}_{s} ∈ {ℳ}^{k}} Pr ( {m}_{s} \vert y ) or equivalently {max}_{{m}_{s} ∈ {ℳ}^{k}} Pr ( {m}_{s} ) f ( y \vert {m}_{s} ) \qquad ( 4 )$$

where ƒ (y|mₛ) is the (joint) probability density function of the received signal y (real-valued random vector) conditioned on the event that the transmitted/stored message is mₛ. Note that in the special case of M-ary IQ modulation embodiment, received signal y is (2n/log₂ M)-dimensional real-valued random vector. If digital circuitry must be used to perform this optimization, received signal y can be quantized to take only discrete set of values and the corresponding probability mass function p(y|mₛ) can be derived from the probability density function characterizing the channel. Again, for the special case of equally likely a priori probability of messages, the optimization is reduced to maximum likelihood detection:

$${max}_{{m}_{s} ∈ {ℳ}^{k}} f ( y \vert {m}_{s} ) \qquad ( 5 )$$

The decoder chooses one of the 2^{k} possible messages. Enumerating over all possible 2^{k} possible messages is computationally inefficient. The methods presented in this document apply evolutionary algorithms such as Estimation-of-Distribution (EDA) algorithms, Cross-Entropy, quantum evolutionary algorithm, swarm intelligence, etc. to optimizations exemplified by (2)(3)(4)(5) in order to embody decoders.

### 2. Decoding Considered as an Optimization Problem

Consider an optimization problem that seeks the best solution from the set, [symbol] , of candidate solutions. The criterion for determining the best solution is represented by a fitness function F(x), xε [symbol] . The higher value of F means the better solution. For decoding purpose, fitness function F can be designed, for example, from (2)(3)(4)(5). A decoding mechanism can perform optimization process to determine the message encoded, where the set, [symbol] , of candidate solutions is the set of possible message sequences or the set of code words in the code employed by the system. There are many ways of representing set [symbol] for embodying a probabilistic learning algorithm. For example, set can [symbol] be a set of binary vectors of dimension d where d is sufficiently large so that 2^{d} is at least the number of code words in the code employed in the system. For another example, set [symbol] can be represented by a set of inter vectors in which each component can have a value in a finite set of integers.

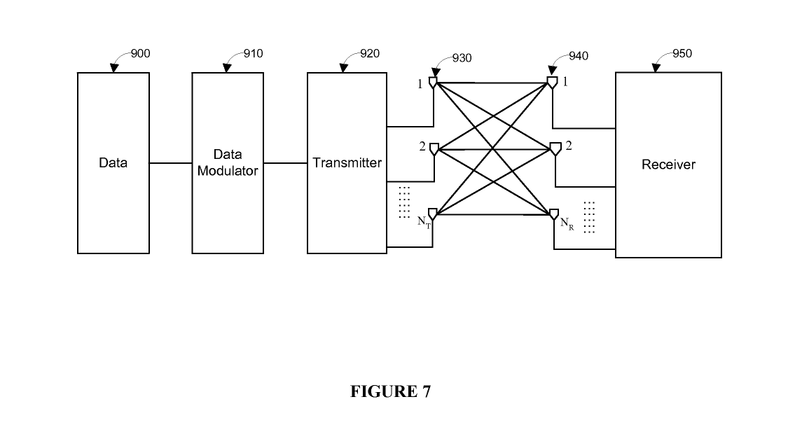

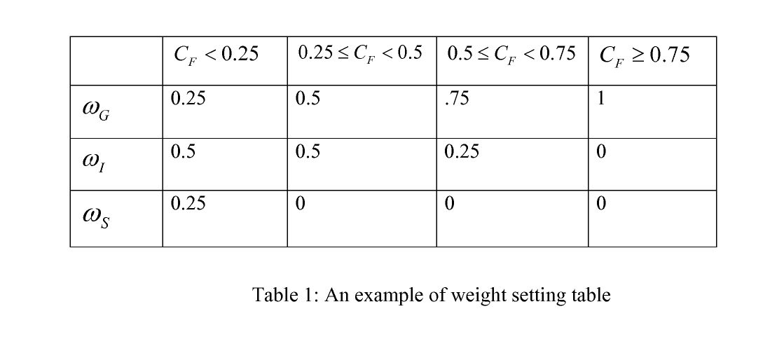

Then, a technique for solving integer programming problem can be applied to solve the optimization problem designed for decoding. For example, any message m in [symbol] can be represented by a k-dimensional binary vector. Then, binary integer programming techniques can be applied to solve optimizations (2), (3), or (4). As an example applying of non-binary integer programming, let us consider the following space-time-coded system. For example, let us consider a communication link constituted by a transmitter having N_{T} transmit antennas and a receiver having N_{R} antennas, as illustrated in FIG. 7. We denote by T the number of time slots in the space-time code block. The input signal in a space-time code block is represented by a complex T×N_{T} dimensional matrix S. In the case of N_{T}=1, the space-time code is reduced to coding only across time. For the linear dispersion space time coding in general, matrix S (the input signal in a space time code block) can be expressed as

S=Σ_{q=1}^{Q}[(α_{q}+jβ_{q})C_{q}+(α_{q}−jβ_{q})D_{q}],

where Q is the number of symbols communicated in a space time code block and α_{q}+jβ_{q}, q=1, . . . , Q are complex numbers that represent the Q symbols. (Note that α_{q} and β_{q} denote the real and imaginary parts of a symbol.) Then, the Q symbols can be represented as a 2Q-dimensional real-valued row vector χ, where components of χ are constituted by α_{q} and β_{q}, q=1, . . . , Q. (e.g., χ=(α₁, β₁, α₂, β₂, . . . , α_{Q}, β_{Q}) In the case of a square (2 L)²-QAM constellation, without loss of generality, components of χ, αᵢ, βⱼ are in {(2k+1)d|k=−L, −L+1, . . . , −1, 0, 1, . . . , L−1} where d is the minimum distance between symbols in the symbol constellation. Then, objective functions of optimizations (2), (3), (4), (5) are respectively

max Pr(α₁,β₁,α₂,β₂, . . . ,α_{Q},β_{Q})Pr(y|S)

[symbol]

max Pr(α₁,β₁,α₂,β₂, . . . ,α_{Q},β_{Q})

Pr(y|Σ_{q=1}^{Q}[(α_{q}+jβ_{q})C_{q}+(α_{q}−jβ_{q})D_{q}])

[symbol]

max Pr(α₁,β₁,α₂,β₂, . . . ,α_{Q},β_{Q})

Pr(y|Σ_{q=1}^{Q}[((2k_{q}^{R}+1)d+j(2k_{q}^{I}+1)d)C_{q}+((2k_{q}^{R}+1)d−j(2k_{q}^{I}+1)d)D_{q}])

max Pr(y|S) [symbol] max Pr(y|Σ_{q=1}^{Q}[(α_{q}+jβ_{q})C_{q}+(α_{q}−jβ_{q})D_{q}])

[symbol]

max Pr(y|Σ_{q=1}^{Q}[((2k_{q}^{R}+1)d+j(2k_{q}^{t}+1)d)C_{q}+((2k_{q}^{R}+1)d−j(2k_{q}^{t}+1)d)D_{q}]),

max Pr(α₁,β₁,α₂,β₂, . . . ,α_{Q},β_{Q})f(y|S)

[symbol]

max Pr(α₁,β₁,α₂,β₂, . . . ,α_{Q},β_{Q})

f(y|Σ_{q=1}^{Q}[(α_{q}+jβ_{q})C_{q}+(α_{q}−jβ_{q})D_{q}])

[symbol]

max Pr(α₁,β₁,α₂,β₂, . . . ,α_{Q},β_{Q})

f(y|Σ_{q=1}^{Q}[((2k_{q}^{R}+1)d+j(2k_{q}^{I}+1)d)C_{q}+((2k_{q}^{R}+1)d−j(2k_{q}^{I}+1)d)D_{q}])

max f(y|S) [symbol] max f(y|Σ_{q=1}^{Q}[(α_{q}+jβ_{q})C_{q}+(α_{q}−jβ_{q})D_{q}])

[symbol]

max f(y|Σ_{q=1}^{Q}[((2k_{q}^{R}+1)d+j(2k_{q}^{I}+1)d)C_{q}+((2k_{q}^{R}+1)d−j(2k_{q}^{I}+1)d)D_{q}])

where the optimization variables are (k₁^{R}, K₁^{I}, k₂^{R}, K₂^{I}, . . . , k_{Q}^{R}, K_{Q}^{I}) with integer constraint k_{q}^{R},K_{q}^{I}ε{(2k+1)d|k=−L, −L+1, . . . , −1, 0, 1, . . . , L−1} for each q. The objective functions for a given y are functions of input symbols (α₁, β₁, α₂, β₂, . . . , α_{Q}, β_{Q}). Therefore, even if integer constraint k_{q}^{R},K_{q}^{I} are relaxed, these objective functions for optimizations (3) and (5) are well defined. Thus, integer programming techniques that uses relaxation of integer constraints (e.g. branch and bound algorithm for bounding the objective for a partitioned constraint sets).

For the case non-square or non-rectangular MQAM, we can add additional constraint (not necessarily containing integer constraints in order to have describe the shape of the symbol constellation in the complex plane.

We now consider a special case of binary code and hard decision decoding system that has a binary symmetric channel [3]. This special case represented by [symbol] ={0,1}= [symbol] and by representing each output signal y as a binary vector in [symbol] Let us denote by mapping χ: [symbol] the code, so each message m in [symbol] is encoded to codeword χ(m). In the case that source message mε [symbol] is equally likely a priori, optimization (3) is reduced to searching for a code c (in [symbol] ) that has shortest Hamming distance from y. That is,

$${min}_{m ∈ {ℳ}^{k}} {‖ y ⊕ χ ( m ) ‖}_{H}$$

where ⊕ denotes addition in the binary field and ∥·∥_{H} denotes Hamming weight.

As a special example of soft decision decoding, we now consider a binary code in a communication system that employs binary phase shift key (BPSK) modulation and has additive white Gaussian noise. We denote by χᵢ (m) the ith bit of codeword χ(m), i=1, 2, . . . , n. Note that χᵢ (m) takes either value 0 or 1. Then, for each message m, the received symbols y=(y₁, y₂, . . . , yₙ) can be represented as

yᵢ=(−1)^{χi(m)}+Wᵢ,i=1,2, . . . ,n

where W₁, W₂, . . . Wₙ are statistically independent identically distributed Gaussian random variables with 0-mean and variance (signal to noise ratio per symbol) σ². Accordingly, the joint distribution of the received signal y=(y₁, y₂, . . . , yₙ) conditioned on source message m is

$$f ( y \vert m ) = {\prod }_{i = 1}^{n} \frac{1}{\sqrt{2 π} σ} exp [ - \frac{{\{ {y}_{i} - {( - 1 )}^{{χ}_{i} ( m )} \}}^{2}}{2 {σ}^{2}} ]$$

In this special case, for each received signal y, finding m that maximizes ƒ (y|m) in set [symbol] is equivalent to minimization:

$${min}_{m ∈ {ℳ}^{k}} {\sum }_{i = 1}^{n} {\{ {y}_{i} - {( - 1 )}^{{χ}_{i} ( m )} \}}^{2} .$$

### 3. Population-Based Probabilistic Learning Algorithms for Decoding

Population-based probabilistic learning algorithms can be generally described as the following pseudo code. We denote by f(x;u), xε [symbol] , a probability distribution f(x;u),xε [symbol] , where u is a parameter that refers to this probability distribution, and the domain of this probability distribution is [symbol] . Denote by x_{B}^{l} the variable that stores the best solution found up to iteration l.
1. Generate an initial sample set of candidate solutions S⁽¹⁾⊂ [symbol] , and initialize iteration (generation) counter l=1;
2. Evaluate fitness values of the sample candidate solutions generated at the current iteration. Update

x_{B}^{l}=arg max_{xε{x}_{_{B}}_{l-1}∪S}_{^{(l)}}F(x);
3. On the basis of the sample candidate solutions generated up to iteration l, design a probability mass function ƒ (x;v^{l+1});
4. In accordance with probability distribution ƒ (x;v^{l+1}), generate a set S^{(l+1)} of candidate solutions;
5. If a termination condition is met, terminate. Otherwise, increase iteration counter l:=l+1 and go to Step 2;
   Probability distribution ƒ (x;u)≡f(x₁, x₂, x₃, . . . ,x_{d};u) can be often specified by L^{d}−1 real numbers, where L is the number of integer values that each component variable Xᵢ can take. Basically, the number of real numbers required to represent the probabilities associated with all possible code words is the number of code words minus one. Updating all these numbers in each iteration in probabilistic learning algorithm is often computationally prohibitive. This document presents several detailed methods to reduce computational complexity.

One methods is to represent the probability distribution as that of independent components of random vector X; that is, to assume that the probability distribution has a product form

f(x₁,x₂,x₃, . . . ,x_{d};u)=f₁(x₁;u)f₂(x₂;u) . . . f_{d}(x_{d};u). (6)

Under this assumption, the probability distribution is specified by (L−1) d real numbers. Another method is to partition the variables of the probability distribution as

{x₁,x₂,x₃, . . . ,x_{d}}=Uᵢ₌₁^{q}χᵢ (7)

where x₁, x₂, . . . , x_{q} are mutually exclusive set of variable use the product form

f(x₁,x₂,x₃, . . . ,x_{d};u)=f₁(y₁;u)f₂(y₂;u) . . . f_{q}(y_{q};u) (8)

where y₁ denotes the vector constituted by the set of variables in χᵢ and fₗ(yₗ;u) denotes the joint distribution of the random variables represented by the members of set χᵢ. Note that distribution fᵢ(yᵢ;u) is represented by L^{|χi|}−1 real numbers, so distribution of the form (8) is represented by Σᵢ₌₁^{q}(L^{|χi|}−1) real numbers.

### 4. Estimation of Distribution Algorithm (EDA) for Decoding

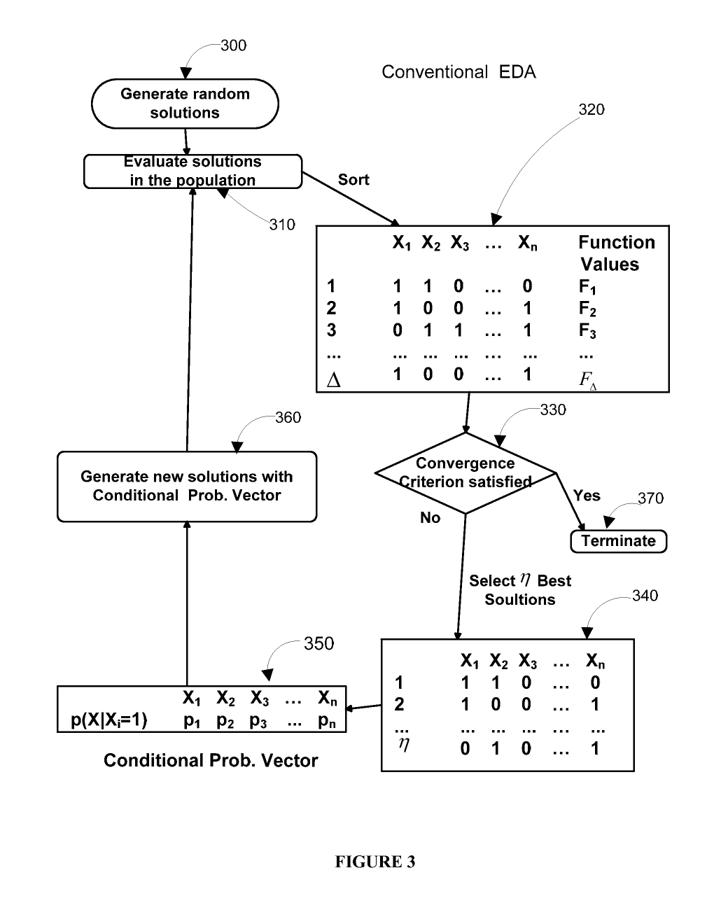

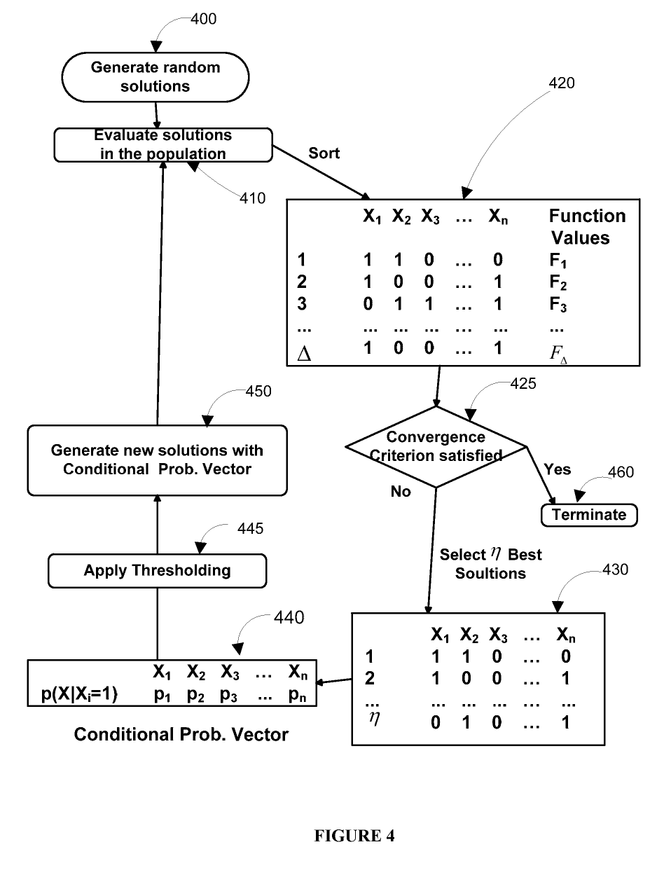

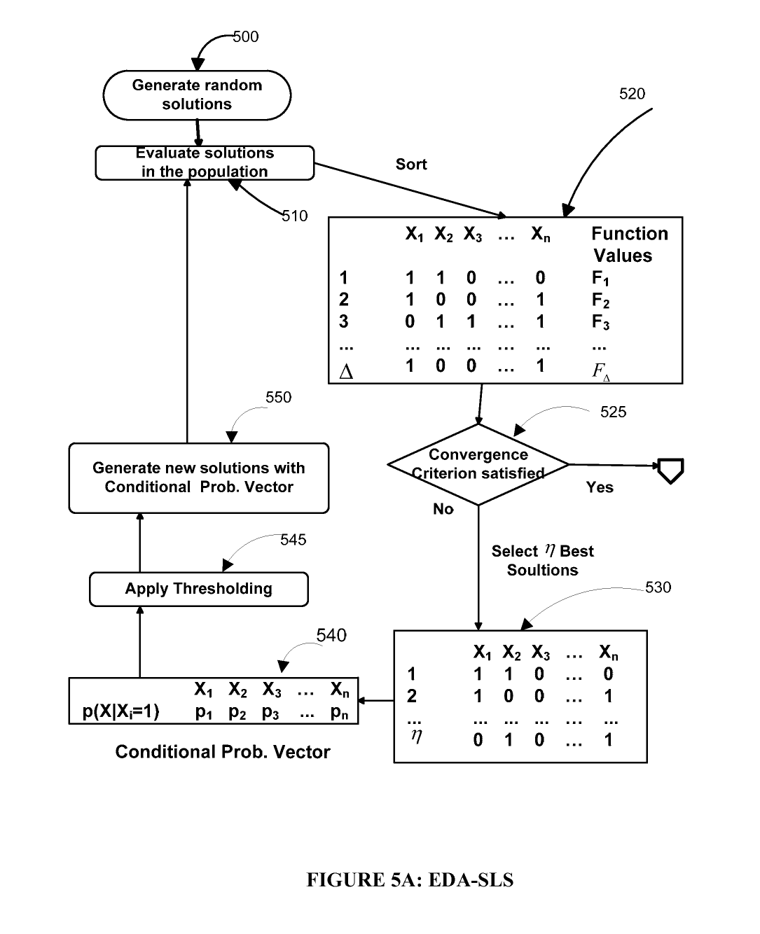

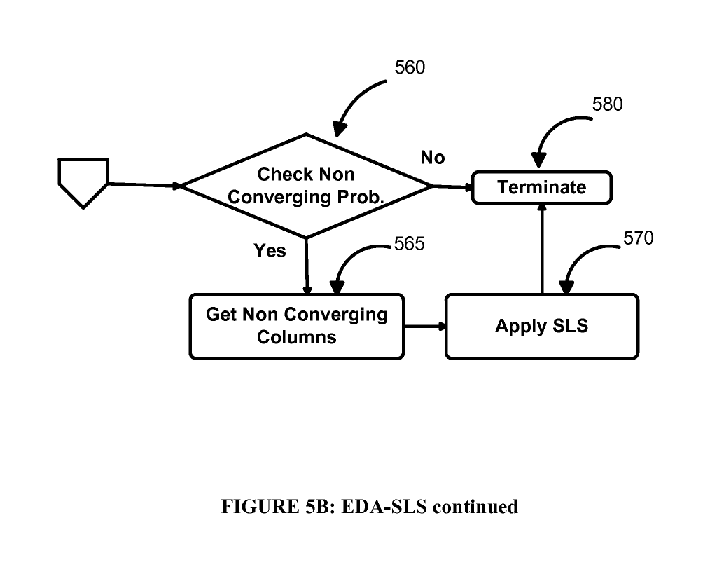

This document includes the description of a decoding method that applies Estimation of Distribution Algorithms (EDAs). EDAs exemplify the class of population-based probabilistic learning algorithms. A typical, conventional EDA is illustrated in FIG. 3. In evolutionary algorithms, new population of individuals is generated at each iteration. These individuals are selected at each iteration from the pool, which contains only the best individuals from the previous iterations. In EDAs, the new population individuals are generated without crossover and mutation operators (as in other evolutionary algorithms); instead, new population individuals are generated on the basis of a probability distribution, which is estimated from the pool of previous iteration. This section presents combining EDA processes and decoding processes for error-control codes. This section also presents how to improve conventional EDA processes.

Application of conventional EDAs to decoding can be characterized by [2] parameters (I, F, Δ, η, pₛ, Dₑₛ, F_{Ter}), where
1. I is the space of all potential solutions (entire search space of individuals). In a decoding application as modeled in the previous section, I= [symbol]
2. F denotes a fitness function. Preferred fitness function in decoding is F(mₛ)=Pr(mₛ)f(y|mₛ),mₛε [symbol] for the case of soft decision decoding and F(mₛ)=Pr(mₛ)f(y|mₛ),mₛε [symbol] in the case of hard decision decoding.
3. Δ is the maximum size of population at a single iteration.
4. η is the number of best candidate solutions selected from Δ individuals at each iteration.
5. pₛ=η/Δ is called selection probability.
6. Dₑₛ is the distribution estimated from η candidate solutions at each iteration.
7. F_{Ter} is the termination criteria.
   A typical EDA is illustrated in FIG. 3, which is described as follows:
   Step 1: Generate initial population of Δ individuals 300. Each individual is designated by a string of length k (k-dimensional vector in I= [symbol] The initial population can be selected on the basis of the code's algebraic structure and the received signal y in a way that individuals in the initial population has good fitness—high values of F(m)=Pr(m)f(y|m) or F(m)=Pr(m)Pr(y|m). Alternatively, the embodied system can randomly generate each individual x^{j}=(x₁^{j}, x₂^{j}, x₃^{j}, . . . , xₖ^{j}), j=1, 2, . . . , Δ in the initial population by equally likely component-wise sampling. In each iteration of EDA, we will denote the current population as

(X¹,X²,X³, . . . X^{Δ})={(x₁¹,x₂¹,x₃¹, . . . ,xₖ¹),(x₁²,x₂²,x₃^{j}, . . . ,xₖ^{j}), . . . ,(x₁^{Δ},x₂^{Δ},x₃^{Δ}, . . . ,xₖ^{Δ})}

Step 2: Evaluate the current population according to the fitness function F. Sort the candidate solutions according to their fitness orders 320.
Step 3: If the best candidate solution satisfies the convergence criterion 330 or the number of iterations exceeds its limit, then terminate 370 else go to step 4.
Step 4: Select the best η candidate solutions 340 from current Δ populations. This selection is accomplished according to the sorted solutions 320.
Step 5: Estimate the joint probability distribution 350 from η best candidate solutions

Dₑₛ=P(x₁,x₂, . . . ,xₖ|Iₜ₋₁^{η}) (6)

Step 6: Generate new Δ−η populations according to this new estimated probability distribution Dₑₛ 360.
Step 7: Go to step 2 and repeat the steps

We note that even for non-binary source (user) symbols, the block of user symbols can be represented by a block of binary bits. That is, the user information is most often represented by binary vectors, and the search space of EDA is most often I= [symbol] with [symbol] ={0,1}. In this binary representation, a method presented in this document includes the following enhancements. Optimization process through an Estimation-of-Distribution algorithm can get stuck in a local optimum due to a premature convergence of the probability distributions or can be slowed down due to no-convergence of the probability distributions. In addition to applying an EDA to decoding, we present a preferred method of avoiding these two problems by adding a threshold 445 on estimated distributions and performing scattered local search (SLS) 570.

Any of probability p₁, p₂ . . . pₖ in 440 and 540 can converge to 1.0 or 0.0 prematurely. In order to thwart such premature convergence, the invention documented here includes an idea of adjusting the distribution p₁, p₂ . . . pₖ after estimating these at each iteration. The adjustment in general can be described as a mapping from the set of n-dimensional vectors, Π≡{(p₁, p₂, . . . , pₖ)|0≦pᵢ≦1, i=1, 2, . . . ,k}, to set Π itself. A preferred embodiment of this idea is to use thresholds. First we address the problem that a probability value prematurely converges to 1. To avoid this, we define thresholds 0.5<y₁, y₂, . . . , yₖ<1. At any iteration, if the probability value in pᵢ, i=1, 2, . . . , k, is greater than y₁, we set that value to y₁, so that some degree of randomness remains in the algorithm until the termination criterion is satisfied. A simpler application of this idea is to set the same threshold y=y₁=y₂= . . . =yₖ. Now we address the problem that a probability value prematurely converges to 0. We define thresholds 0<α₁, α₂, . . . , αₖ<0.5. At any iteration, if the probability value in pᵢ, i=1, 2, . . . ,k, is less than αᵢ, we set that value to αᵢ, so that some degree of randomness remains in the algorithm until the termination criterion is satisfied. A simpler application of this idea is to set the same threshold α=α₁=α₂= . . . =αₖ

When the termination criterion 525 is satisfied, it may be observed that some values in p₁, p₂ . . . , pₖ have never shown evidence of convergence in the evolutionary pattern. We present the method of applying scattered local search (SLS) in that case. Now we describe the SLS. Suppose that some probability values among p₁, p₂ . . . pₖ have not shown convergence when the termination criterion 525 is satisfied—e.g., pᵢ, pⱼ and pₗ have not converged to γ or α. We denote by N_{c} the number of non-converging probability values in the k-tuple, p₁, p₂ . . . pₖ. We apply exhaustive search on these N_{c} bits 570 and call it scattered local search (SLS). Since N_{c} is very small as compared to k, it will not add any significant extra computational complexity to the system. The simulation results show that performance of EDA with SLS is better than EDA.

We now consider a special case of binary code and hard decision decoding system that has a binary symmetric channel [3]. This special case represented by [symbol] ={0,1}=C and by representing each output signal y as a binary vector in [symbol] Let us denote by mapping χ: [symbol] the code, so each message m in [symbol] is encoded to codeword χ(m). In the case that source message mε [symbol] is equally likely a priori, optimization (3) is reduced to searching for a code c (in Cⁿ) that has shortest Hamming distance from y. That is,

$${min}_{m ∈ {ℳ}^{k}} {‖ y ⊕ χ ( m ) ‖}_{H}$$

where ⊕ denotes addition in the binary field and ∥·∥_{H} denotes Hamming weight.

As a special example of soft decision decoding, we now consider a binary code in a communication system that employs binary phase shift key (BPSK) modulation and has additive white Gaussian noise. We denote by χᵢ (m) the ith bit of codeword χ(m), i=1, 2, . . . , n. Note that χᵢ (m) takes either value 0 or 1. Then, for each message m, the received symbols y=(y₁, y₂, . . . , yₙ) can be represented as

yᵢ=(−1)^{χi(m)}+Wᵢ,i=1,2, . . . ,n

where W₁, W₂, . . . Wₙ are statistically independent identically distributed Gaussian random variables with 0-mean and variance (signal to noise ratio per symbol) σ². Accordingly, the joint distribution of the received signal y=(y₁, y₂, . . . , yₙ) conditioned on source message m is

$$f ( y \vert m ) = {\prod }_{i = 1}^{n} \frac{1}{\sqrt{2 π} σ} exp [ - \frac{{\{ {{y}_{i} ( - 1 )}^{{χ}_{i} ( m )} \}}^{2}}{2 {σ}^{2}} ]$$

In this special case, for each received signal y, finding m that maximizes f(y|m) in set [symbol] is equivalent to minimization:

$${min}_{m ∈ {ℳ}^{k}} {\sum }_{i = 1}^{n} {\{ {y}_{i} - {( - 1 )}^{{χ}_{i} ( m )} \}}^{2} .$$

### 5. Cross-Entropy Optimzation for Decoding

Cross-Entropy optimization is also an example in the class of population-based probabilistic learning algorithms. This document includes the description of a decoding method embodiment that applies Cross-Entropy (CE) optimization. We first provide a brief introduction to CEO. A detailed description of CEO method can be found in [6]. Consider a maximization problem:

$$maximize F ( x ) \\ subject to x ∈ 𝒳 \qquad ( 11 )$$

Let us denote a maximum by x* and the maximal function value by y*.

The probabilistic evolutionary algorithm in general randomly generates a population (subset of [symbol] ) of candidate solutions (elements of constraint set [symbol] ) in accordance with some probability distribution at each iteration. Then, good candidate solutions are selected from the population and the probability distribution is updated on the basis of the selected good candidate solutions. In the next iteration, a new population of candidate solutions is generated according to this updated probability distribution. In order to focus on the essential idea of CEO, let us consider an arbitrary probability mass function (pmf) f(x;u), xε [symbol] , where u is a parameter that refers to this pmf, and the domain of this pmf is [symbol] . A simple example would be a pmf that has the value 1/| [symbol] |, ∀xε [symbol] , which represents the equally likely choice of candidate solutions from set [symbol] . Suppose a pmf f(x;u) is used at a stage (at an iteration) in the algorithm. Hypothetically, if pmf

$$\begin{matrix}g ( x ; γ , u ) = \frac{{I}_{\{ F ( x ) \geq γ \}} f ( x ; u )}{{\sum }_{x ∈ 𝒳} {I}_{\{ F ( x ) \geq γ \}} f ( x ; u )} \\ ≡ \frac{{I}_{\{ F ( x ) \geq γ \}} f ( x ; u )}{l ( u , γ )}\end{matrix} \qquad ( 12 )$$

is used¹ as the pmf at the next iteration, then every sample generated from this distribution will be a high-quality candidate (a candidate whose objective function value is a least γ). Hypothetically, if γ=γ* were used in (12), then pmf g(x;γ*,u) would only generate random samples that are optimal because all probability mass is concentrated in the optimal solution or optimal solutions. However, the optimal value γ* is unknown to the algorithm. Instead of using pmƒ (12) with γ=γ*, a CEO algorithm cautiously increases γ at each new iteration on the basis of samples (candidate solutions) Xᵢ, i=1, 2, . . . ,┌ randomly generated in accordance with pmf f(x;u).

Another hurdle in using (12) is that pmf in (12) is difficult to compute even for a known γ, because computation of

l(u,γ)≡Σ_{xε} [symbol] I_{{F}(x)≧γ}f(x;u)

could be prohibitive for the case of a large set [symbol] . The CEO algorithm uses in place of (12) the pmf that is closest to (12) in terms of Kullback-Leibler (KL) distance (cross entropy) [5]. That is, the pmf v that minimizes

$$\begin{matrix}D ( g ( x ; γ , u ) \vert \vert f ( x ; v ) ) = {\sum }_{x ∈ 𝒳} g ( x ; γ , u ) ln \frac{g ( x ; γ , u )}{f ( x ; v )} \\ = {\sum }_{x ∈ 𝒳} g ( x ; γ , u ) ln g ( x ; γ , u ) - \\ {\sum }_{x ∈ 𝒳} g ( x ; γ , u ) ln f ( x ; v )\end{matrix}$$

I_{{F(x)≧γ}} is an indicator function and defined as

$${I}_{\{ F ( x ) \geq γ \}} = \{ \begin{matrix}1 , & if F ( x ) \geq γ \\ 0 , & otherwise\end{matrix}$$

Minimizing this KL-distance by choosing pmf v is equivalent to maximizing

Σ_{xε} [symbol] g(x;γ,u)ln f(x;v),

This is also equivalent to maximizing

Σ_{xε} [symbol] I_{{F(x)≧γ}}f(x;u)ln f(x;v)=Eᵤ[I_{{F(X)≧γ}}ln f(X;v)], (13)

where Eᵤ( )denotes expected value in accordance with pmf u of random variable X. In order to avoid computational complexity, a CE algorithm finds in the family of pmfs, a pmf v that results in the largest

$$\frac{1}{Γ} {\sum }_{i = 1}^{Γ} {I}_{\{ F ( {X}_{i} ) \geq γ \}} ln f ( {X}_{i} ; v ) , \qquad ( 14 )$$

which is the estimate oƒ (13) on the basis of the samples Xᵢ, i=1, 2, . . . ,┌ (randomly generated in accordance with pmf ƒ (x;u)). In general, CE algorithm proceeds as:
1. Define v⁰=u, Set l=1(Iteration counter)
2. Generate samples X₁, . . . , X_{┌} from the density f(:,v^{l}^{¹}).
3. Evaluate the objective function and order them from the smallest to largest: F₁≦F₂≦ . . . ≦F_{┌}. Then set the (1-p)-quantile γ^{l} as γ^{l}=F_{(|(1-p)┌|).}
4. Use the same samples Xᵢ, . . . , X_{┌} to obtain a new pmf that results in largest (14). Denote this pmf by index v^{l}.
5. If stopping criterion satisfied then terminate otherwise set l=l+1 and reiterate from step 2.

### 6. Ant Colony Optimization for Decoding

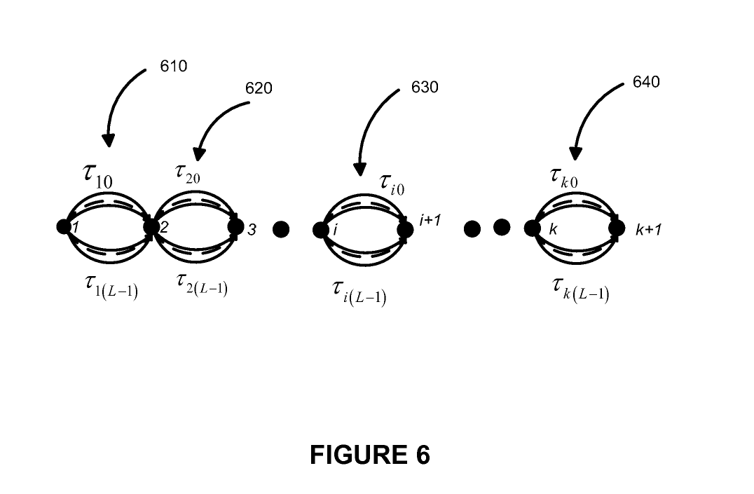

Ant colony optimization (ACO) [4][9] is a swarm-like stochastic heuristic optimization procedure to solve complex combinatorial optimization problems. ACO takes inspiration from the foraging behavior of ants. These ants deposit pheromone on the ground in order to mark some favorable path that should be followed by others ants of the colony. Each ant contributes its effort to the solution. The main idea of ant colony optimization is the cooperation of a number of artificial ants to find shortest path. In ACO, the ants construct the solution by traveling through the edges of graph as shown in FIG. 6. ACO processes can be combined into decoding processes to form methods for error-control codes.

In general, ACO can be characterized by parameters

(Iₛ, F, N, k, \hat{X}^{l}, τ^{l}, B_{g}^{l}, B_{I}^{l}, B_{S}^{l=0}, ω, ε, C_{F}, F_{Ter}),
where
1. Iₛ is the space of all potential solutions. In a decoding application as modeled in section 1, I= [symbol]
2. F denotes a fitness function. In this document, we defined F so that higher value means better fit. (Another convention is to use −F as a cost function so that lower value of −F means better fit.) Preferred fitness functions in decoding are

F(m)=Pr(m)f(y|m),mε

[symbol]

for the case of soft decision decoding and

F(m)=Pr(m)Pr(y|m),mε

[symbol]

in the case of hard decision decoding.
3. N is the size of the ant population (The number of ants that cooperate together to search in space of candidate solutions).
4. k is the number of edges in a path. (The number of edges used by each ant to construct its solution by a sequential walk from node 1 to k+1).
5. \hat{X}^{l}=[X₁^{l}, X₂^{l}, . . . , X_{N}^{l}] represents the paths adopted by the ants at the lₜₕ iteration, where Xₘ^{l}, m=1, 2, . . . , N, represents the path adopted by the m^{th} ant. Components of vector Xₘ^{l} are denoted as

Xₘ^{l}=(x_{m,1}^{l},x_{m,2}^{l}, . . . ,x_{m,k}^{l}).

In the special case illustrated in FIG. 6, each component variable can take values 0, 1, . . . , L−1. For binary formulation we would have x_{m,i}^{l}ε{0,1}, i=1, 2, . . . , k.
6. τ^{l} represents a set of pheromone values in all the edges at the l^{th} iteration. τᵢ₀^{l} represents the pheromone value for edge ‘0’ between node i and i+1. Similarly τᵢₓ represents the pheromone value for edge ‘ₓ’ between node i and i+1. These values are used for an ant to randomly choose an edge between nodes in its path. τᵢₓ^{l} can be viewed as the probability that an ant chooses edge x between node i and i+1 at the lth iteration.
7. B_{g}^{l}=(b_{g,1}^{l}, b_{g,2}^{l}, . . . , b_{g,k}^{l}) is a vector that represents the globally best path travelled by the ants up to the lₜₕ iteration in terms of fitness function F. Each component b_{g,i}^{l} takes values form 0, 1, . . . , L−1 and indicates the edge from node i to i+1 in the globally best path.
8. B_{I}^{l}=(b_{I,1}^{l}, b_{I,2}^{l}, . . . , b_{I,k}^{l}) is a vector that represents the best path travelled by the ants at the lₜₕ iteration in terms of fitness function F. Each component b_{I,i}^{l} takes values form 0, 1, . . . , L−1 and indicates the edge from node i to i+1 in the best path at the lth iteration. B_{I}^{l} does not track the previous best paths up to (l−1)th iteration.
9. B_{S}^{l=0}=(b_{S,1}^{I=0}, b_{S,2}^{l=0}, . . . , b_{S,k}^{l=0})=B_{I}⁰ is a vector that represents the best path travelled at the initial iteration l=0 in terms of fitness function F. Each component b_{S,i}^{l} take values form 0, 1, . . . , L−1 and indicates the edge from node i to i+1. B_{S}^{l=0}=(b_{S,1}^{I=0}, b_{S,2}^{l=0}, . . . , b_{S,k}^{l=0}) is also referred to as the start best
10. ω_{G},ω_{I} and ω_{S} are adaptive weight parameters associated with B_{g}^{l}, B_{I}^{l} and B_{S}^{l=0}, respectively. These weights are used in updating τ^{l} at each iteration on the basis of the paths explored by the ants. These weights must always add to 1. That is, ω=ω_{G}+ω_{I}+ω_{S}=1.
11. ε is the evaporation parameter. This parameter is used in updating τ^{l} at each iteration
12. C_{F}^{l} is the convergence indicating variable, which is computed form the current pheromone values and indicates how close the process is to obtaining a final solution. Different ways of observing the convergence behavior can be constructed and employed. As an example of convergence indicating variable for ACO with multiple edges between nodes, an embodiment of the decoding method can use definition

$${C}_{F}^{l} = {\sum }_{i = 0}^{k} \frac{\vert {max}_{0 \leq x \leq L - 1} ( {τ}_{ix}^{l} ) - {min}_{0 \leq x \leq L - 1} ( {τ}_{ix}^{l} ) \vert}{k} , \qquad ( 7 )$$

where max_{0≦x≦L-1} (τᵢₓ^{l}) is the maximum value of the pheromone among all edges from node i to i+1 and min_{0≦x≦L-1} (τᵢₓ^{l}) is the minimum value of the pheromone among all edges from node i to i+1. In accordance with this definition, we have 0≦C_{F}^{l}≦1. As iterations progress, a superior path in terms of fitness function emerges and the pheromone values along the edges in the superior path dominate. This dominance is translated into high vales of C_{F}^{l}. Therefore, a high value of C_{F}^{l} indicates that the process is mature at the lth iteration and is close to producing a solution. The convergence indicating variable can be used in determining which values the weight parameters ω_{G},ω_{I}, and ω_{S} are set to at each iteration l. These weights can be used to influence the pheromone update procedure and can be adapted in accordance of different stages of the process' maturity to make the process computationally efficient. One example of adapting ω_{G},ω_{I} and ω_{S} is shown in Table 1.
13. F_{Ter} is the termination criteria.

In the decoding process modeled in section 1, a source (user) message is represented by k-dimensional vector mₛ in [symbol] In order to find the source message on the basis of the received signal, the decoding process can construct [symbol] edges between each pair of neighboring nodes in the graph illustrated in FIG. 6 for ant colony optimization. The set of [symbol] edges connecting node i and node i+1 has one-to-one correspondence with the set of alphabet [symbol] Therefore, the choice of an edge between node i and node i+1 represents the symbol value in the ith component of source message mₛ. Correspondingly, a path from node 1 to node k+1 uniquely represents a source message mₛ. The present invention determines the source message by finding the best path from node 1 to node k+1 through ant colony optimization.

### Decoding Process

The number of edges, L, between neighboring nodes, say from node i to i+1 can be set differently for different embodiments. For example, L can be set as [symbol] and we can consider [symbol] paths from node 1 to node k+1 for ant colony optimization, where each path corresponds to a code word. Another possible embodiment is to group multiple symbols into a set and represent each member of this set by an edge in the ant colony optimization. For example, [symbol] possible sequences of two symbols can be represented by [symbol] edges between neighboring nodes and 1+k/2 nodes in ant colony optimization. For another example, [symbol] possible sequences of three symbols can be represented by [symbol] edges between neighboring nodes and 1+k/3 nodes in ant colony optimization, etc. In fact, the number of edges between adjacent nodes does not have to be identical. For example, we can set up [symbol] edges from node 1 to node 2 to represent the first four symbols of the code word and set up [symbol] edges from node 2 to node 3 to represent the fifth symbol of the code word, etc.

For the purpose of simple illustration, we use and example of setting L= [symbol] paths from any node i to i+1, for i=1, 2, . . . , k. The decoding algorithm is describe as the following.

Step 1: Initialize values τᵢₓ⁰ for x=0, 1, 2, . . . , L−1 and i=1, 2, . . . , k in such a way that Σₓ₌₀^{L-1}τᵢₓ⁰=1 for each i. A common way of initialization is to set τᵢ₀⁰=τᵢ₁⁰= . . . τ_{i(L-1)}⁰=1/L. In decoding process more weight can be assign to a more significant path at the start. The significant path can be determined either by hard decision or any other technique.
Step 2: Generate each ant s path based on pheromone values according to the relation

$${x}_{mi}^{l} = \{ \begin{matrix}0 & with probability {τ}_{i 0}^{l} \\ 1 & with probability {τ}_{i 1}^{l} \\ 2 & with probability {τ}_{i 2}^{l} \\ ⋮ & ⋮ \\ L - 1 & with probability {τ}_{i , L - 1}^{l} ,\end{matrix} \\ for i = 1 , 2 , … , k \qquad ( 8 )$$

for in =1, 2, . . . , N. The superscript/is the iteration.
Step 3: Evaluate the paths with fitness function F. Determine global best B_{g}^{l}, iteration best B_{I}^{l} and start best B_{S}^{l=0}.
Step 4: Update the iteration counter.
Step 5: Update the pheromone. The following specific embodiment exemplifies the pheromone update. For ease of description, we first define indicator functions,

$${ϒ}_{i , x} ( {b}_{g , i}^{l} = x ) = \{ \begin{matrix}1 & {b}_{g , i}^{l} = x \\ 0 & otherwise\end{matrix} \\ for i = 1 , 2 , … , k and x = 0 , 2 , … , L - 1 \\ {ϒ}_{i , x} ( {b}_{I , i}^{l} = x ) = \{ \begin{matrix}1 & {b}_{I , i}^{l} = x \\ 0 & otherwise\end{matrix} \\ for i = 1 , 2 , … k and x = 0 , 2 , … , L - 1 \\ {ϒ}_{i , x} ( {b}_{S , i}^{l = 0} = x ) = \{ \begin{matrix}1 & {b}_{S , i}^{l = 0} = x \\ 0 & otherwise\end{matrix} \\ for i = 1 , 2 , … k and x = 0 , 2 , … , L - 1 \qquad ( 9 )$$

An embodiment of the pheromone update rule is

τᵢₓ^{l}=(1−ε)τᵢₓ^{l-1}+ε(ω_{g}γ_{i,x}(b_{g,i}^{l}=x)+ω_{I}γ_{i,x}(b_{I,i}^{l}=x)+ω_{S}γ_{i,x}(b_{S,i}^{l=0}=x)) for, i=1,2, . . . k and x=0,2, . . . L−1 (10)

The updated pheromone value depends on pervious pheromone values and the weighted global, iteration and start best paths. Parameter ε is called evaporation parameter and is initialize as ε=ε₀ where ε₀ is any suitable value with the condition ε₀≦1. In each iteration the evaporation parameter can be adjusted; for example, as ε:=δε, where δ≦1.
Step 6: Update the convergence indicating variable

$${C}_{F}^{l} = \frac{{\sum }_{i = 0}^{k} \vert {max}_{0 \leq x \leq L - 1} ( {τ}_{ix}^{l} ) - {min}_{0 \leq x \leq L - 1} ( {τ}_{ix}^{l} ) \vert}{k}$$

Step 7: If convergence criterion satisfied, then terminate; else, go to step 2.

The methods presented in this document includes the one that allows for more than two edges between neighboring nodes in ant colony optimization; that is, applying a non-binary ACO to decoding.

### 7. Methods of Generating the Initial Population

In population-based probabilistic learning algorithms, the quality of produced solutions after a given number of iterations often depends on the selection of the initial population. Equally likely selection among all code words is one way of making up the initial population. Intuitively, inclusion of many members with good fitness in the initial population (initial positions with good fitness) should improve performance of the algorithms. This section presents other methods that can improve the performance of decoding.

### A. Hard Decision Decoding

To illustrate a method of generating initial population of a given size (Δ as denoted for EDA in section) let us consider an exemplary case of binary code and hard decision decoding system that has a binary symmetric channel [3]. This special case represented by [symbol] ={0,1}= [symbol] and by representing each output signal y as a binary vector in [symbol] . Let us denote by mapping χ: [symbol] the code, so each message mₛ in [symbol] is encoded to code word χ(mₛ). For the purpose of illustration we consider a linear code, in which codeword χ(mₛ) for source message mₛ is related to mₛ by a generator matrix G producing as χ(mₛ)=mₛG. We denote by H the parity check matrix of the code. Then, any codeword χ(m′) has property χ(m′)H^{T}=0. For each received signal yεCⁿ, decoder can compute syndrome yH^{T}. The shortest-Hamming-distance decoding looks for error vector eεCⁿ that has the minimal Hamming weight ∥e∥_{H} under the constraint eH^{T}=yH^{T}. Then, the decoder decides that y+e is the codeword transmitted/stored and the source message is mₛ that satisfies y+e=mₛG. Finding the error vector e can be computationally overwhelming for a code with a large block size (large n and k). The application of heuristic algorithms to decoding can reduce the computational complexity. In order to generate initial population/positions, we can take note that constraint eH^{T}=yH^{T} has n binary variables in vector e and n−k linear equality constraints in the binary field (GF(2)). Therefore, even if we choose arbitrary k components of e and set their values to be 0, we treat the rest n−k variables as unknown variables and solve the system of binary linear equations eH^{T}=yH^{T} for those unknown variables. (A motivation of setting k components of e to 0 is to make Hamming weight ∥e∥_{H} small.) For example, let us consider setting to 0 variables e₁, e₂, . . . , eₖ of vector e=(e₁, e₂, . . . , eₖ, eₖ₊₁, . . . , eₙ). Correspondingly, we can partition the parity check matrix H=[H₁,H₂] where H₁ is (n−k)×k matrix and H₂ is (n−k)×(n−k) matrix.) Then, constraint eH^{T}=yH^{T} is reduced to (eₖ₊₁, . . . , eₙ)H₂^{T}=yH^{T} for setting e₁=e₂= . . . =eₖ=0. A solution to (eₖ₊₁, . . . , eₙ) H₂^{T}=yH^{T} can be algebraically solved by various methods such as Gaussian elimination in the binary field {0,1}. If matrix H₂ is non-singular, there will be a unique vector (eₖ₊₁, . . . , eₙ) that satisfies (eₖ₊₁, . . . , eₙ)H₂T=yH^{T}. If H₂ is singular, the process may be able to obtain multiple values of vector (eₖ₊₁, . . . , eₙ) that satisfy (eₖ₊₁, . . . , eₙ) H₂^{T}=yH^{T}. The process can explore (not necessarily exhaustively) through combinations of k components to set to 0 in vector e and obtain a solution for the rest components to satisfy eH^{T}=yH^{T}. For different such combinations the solution vector e=(e₁, e₂, . . . , eₖ,eₖ₊₁, . . . , eₙ) may coincide, but this process can still generate multiple values of e=(e₁,e₂, . . . ,eₖ,eₖ₊₁, . . . , eₙ) and all these values of e have Hamming weights less than or equal to (n−k). Now, y+e for each of these solutions e is a codeword, and each codeword has a corresponding source message mₛ. The process can use some of these code words as some of the members of the initial population in probabilistic learning algorithms.

We now discuss another method of generating an initial population for probabilistic learning algorithms. For simple illustration of an embodiment, we now consider a binary linear systematic code. Each code word in a linear systematic code can be represented by a binary row vector of dimension n, where n bits in the vector has k message bits and (n−k) parity check bits. From a received n-dimensional binary signal y of, we can select k bits that are in the positions of message bits of a code word and represent those selected bits by a k-dimensional vector m₀ε [symbol] , as denoted in expressions (1)-(5), representing a candidate solution. An embodiment of a decoder employing a probabilistic learning algorithm can include this candidate solution in the initial population. Then, an embodiment can consider including all or some of k message vectors that have Hamming distance 1 from m₀. Then, we can consider the set of code words that have Hamming distance 2 from m₀ and include some or all of these code words. Generally, we can consider the set of code words that have Hamming distance less than some number hᵣ and include some or all of these code words.

### B. Soft Decision Decoding:

Even for a soft decision decoding system, the process can perform demodulation first to obtain initial population (positions). After the initial population is generated, the process can run a probabilistic learning algorithm for soft decision decoding—namely, use the fitness function for the soft decision decoding.

### 8. Combination of Syndrome Decoding and Evolutionary Algorithms

For the case of hard decision decoding for linear codes in general, a variety of syndrome decoding methods such as the standard array decoding and step-be-step decoding [7] are already known. These methods work well for a modest block sizes. However, for a code with a large block size (e.g., capacity approaching low density parity check (LDPC) codes), the number of array elements becomes too large for efficient implementation. For example, for a binary (n,k) block code, the number of syndrome sequences is 2^{n-k}. The method being presented in this section maintains a partial list of syndromes in order to keep the size of the array implementable. In decoding on the basis of received signal y, if its syndrome yH^{T} is in the partial list, then use the known syndrome decoding techniques such as reading the syndrome's coset leader and determine the transmitted codeword on the basis of the received signal y and the coset leader. Or, the process can employ the “step-by-step” decoding [p. 78, 7] to determine the codeword transmitted. If the syndrome yH^{T} is not in the process' partial list, then the process runs the heuristic algorithms such as the ones presented in the previous sections.

1. A method for decoding data, the method comprising:
receiving a set of signals carrying an encoded source data sequence, the source data sequence comprising a plurality of elements;
constructing a fitness function;
obtaining an initial possible solution set comprising a plurality of possible data sequences, and making the initial possible solution set a current possible solution set;
generating additional possible solution sets by:
a) determining a fitness of each of the possible data sequences in the current possible solution set using said fitness function;
b) constructing one or more additional possible data sequences on the basis of the current and previous possible solution sets and fitnesses of their members; and
c) creating a new current possible solution set including at least the additional possible data sequences said in b); and,
iterating a) through c) until a termination condition is satisfied.

2. A method according to claim 1 wherein:
the source data sequence has a vector representation in which each source data sequence can be represented by a specific selection of component values in a vector comprising one or more components, each component having a value selected from a corresponding finite set of valid values; and
obtaining an initial possible solution set comprises:
a) representing the received signals that carry an encoded source data sequence by a vector comprising components corresponding to the components of the source data sequence and additional components; and
b) selecting from the vector representing the received signals the components that correspond to the components of the source data sequence; and
c) constructing a vector comprising the selected components said in b); and
d) including the vector said in c) in the initial possible solution set.

3. A method according to claim 1 wherein:
the source data sequence has a vector representation in which each source data sequence can be represented by a specific selection of component values in a vector comprising one or more components, each component having a value selected from a corresponding finite set of valid values; and
obtaining an initial possible solution set comprises:
a) representing the received signals that carry an encoded source data sequence by a vector comprising components corresponding to the components of the source data sequence and additional components; and
b) selecting from the vector representing the received signals the components that correspond to the components of the source data sequence; and
c) constructing a vector comprising the selected components said in b); and
d) constructing a distance metric among the vectors, the metric that determines the distance between a pair of vectors;
e) constructing a set of vectors whose distance from the vector said in c) is less than a threshold;
f) including in the initial possible solution set some or all of vectors selected from the set said in e).

4. A method according to claim 3 wherein:
each component of the vector representation has a value selected from a set having two elements; and the distance metric is Hamming distance.

5. A method according to claim 3 wherein:
the source data sequence is encoded by a linear block code.

6. A method according to claim 3 wherein:
constructing one or more additional possible data sequences on the basis of the current and previous possible solution sets and fitnesses of their members comprises:
identifying a fittest subset of the plurality of possible data sequences in the current possible solution set for which the fitnesses are best; and
based on the fittest subset, establishing an estimated probability distribution, the estimated probability distribution comprising a set of probability values, the probability values corresponding to possible values for elements of the data sequence; and
constructing one or more additional possible data sequences consistent with the estimated probability distribution.

7. A method according to claim 6 wherein:
the estimated probability distribution has a representation as a collection of sub-distributions, each of the sub-distributions associated with a subset comprising one or more components in the vector representation of the data sequences; and
each sub-distribution comprises an array of subset probability values, the subset probability values representing likelihoods that the one or more components of the associated subset of components of the vector representation take specific valid values of the corresponding sets of valid values;
wherein establishing the estimated probability distribution comprises setting values for the components of the arrays of the sub-distributions.

8. A method according to claim 7 wherein establishing the estimated probability distribution comprises:
for each of the sub-distributions, setting the probability values for the corresponding array of subset probability values according to a proportion of the possible data sequences of the fittest subset that have the corresponding value or values in the associated subset of components of the vector representation.

9. A method according to claim 8 wherein establishing the estimated probability distribution comprises:
setting the corresponding probability value to be greater than the proportion when the proportion is lower than a first threshold; and
setting the corresponding probability value to be less than the proportion when the proportion is greater than a second threshold.

10. A method according to claim 7 comprising:
identifying a non-converged set comprising those of the subdistributions for which none of the subset probability values is closer to 1 than a threshold; and,
constructing a solution vector representing the source data sequence and performing an exhaustive search to determine values for those of the components of the solution vector that correspond to the sub-distributions of the non-converged set that result in the solution vector having the best fitness.

11. A method according to claim 6 wherein establishing the estimated probability distribution comprises setting the probability values such that all of the probability values lie in a range between a lower value representing a non-zero probability and an upper value representing a probability of less than certainty.

12. A method according to claim 6 wherein creating the new current possible solution set comprises including in the new current possible solution set one or more of the possible data sequences of the fittest subset.

13. A method according to claim 6 wherein:
establishing the estimated probability distribution comprises setting each of the probability values based on a proportion of the corresponding elements in the possible data sequences of the fittest subset that have a corresponding value or set of values.

14. A method according to claim 13 comprising setting the corresponding probability value to be greater than the proportion when the proportion is lower than a first threshold; and setting the corresponding probability value to be less than the proportion when the proportion is greater than a second threshold.

15. A method according to claim 14 comprising, if the proportion is lower than the first threshold, setting the corresponding probability value to be equal to the first threshold.

16. A method according to claim 14 comprising, if the proportion is greater than the second threshold, setting the corresponding probability value to be equal to the second threshold.

17. A method according to claim 14 wherein separate first thresholds are provided for each of a plurality of the values.

18. A method according to claim 3 wherein obtaining said possible solution set comprises performing a sub-optimal search algorithm.

19. A method according to claim 3 wherein constructing the one or more additional possible data sequences comprises generating one or more possible solutions in accordance with a quantum-evolutionary algorithm

20. A method according to claim 3 wherein constructing the one or more additional possible data sequences comprises generating one or more possible solutions in accordance with a cross-entropy optimization algorithm.

21. A method according to claim 3 wherein constructing the one or more additional possible data sequences comprises generating one or more possible solutions in accordance with a biogeography-based optimization algorithm.

22. A method according to claim 3 wherein constructing the one or more additional possible data sequences comprises generating one or more possible solutions in accordance with an ant colony optimization algorithm.
